(19) United States
(12) Patent Application Publication
(10) Pub. No.: US 2024/0222070 A1
(43) Pub. Date: Jul. 4, 2024

(54) XRAY DIFFRACTION ANGLE VERIFICATION IN AN ION IMPLANTER

(71) Applicant: Applied Materials, Inc., Santa Clara, CA (US)

(72) Inventors: Stephen Krause, Ipswich, MA (US); Gary J. Rosen, Manchester, MA (US); Matthew Gaucher, North Chatham, MA (US); Jay T. Scheuer, Rowley, MA (US); Frank Sinclair, Hartland, ME (US); Jonathan Lowder, Atlanta, GA (US); Pratim Palit, Reading, MA (US); Daniel Hall, West Windsor, VT (US)

(21) Appl. No.: 18/387,987

(22) Filed: Nov. 8, 2023

Related U.S. Application Data
(63) Continuation-in-part of application No. 18/091,041, filed on Dec. 29, 2022.

(51) Int. Cl. H01J 37/304; H01J 37/244; H01J 37/317

(52) U.S. Cl. CPC H01J 37/304; H01J 37/244; H01J 37/3171; H01J 2237/24578

(57) ABSTRACT

An ion implanter to facilitate channeling of an ion beam into a crystalline structure of a workpiece is disclosed. The ion implanter comprises an ion source to generate an ion beam, a platen to support the workpiece having the crystalline structure, an Xray source to generate an Xray beam, wherein at least a portion of the Xray beam impacts the workpiece to produce diffracted Xrays, an Xray detector positioned to receive the diffracted Xrays, and a controller, in communication with the Xray source, the platen, and the Xray detector. The controller contains instructions, which enable the ion implanter to perform a rocking curve test after the workpiece is disposed on the platen and calculate an orientation of the platen for an ion implant process based on a result of the rocking curve test to facilitate channeling of the ion beam into the crystalline structure of the workpiece.

Embodiments of the present disclosure relate to an ion implanter that performs angular alignment prior to implantation using Xray diffraction (XRD).

### BACKGROUND

Silicon has been the primary material used for semiconductor workpieces for many years. Silicon workpieces have been used to create transistors, memory elements, amplifiers and other devices.

Recently, more semiconductor devices are being manufactured using alternative workpieces having various crystalline structures. Some of these alternative workpieces include silicon carbide (SiC), gallium nitride (GaN), gallium arsenide (GaAs) and others.

In some scenarios, it is desirable to perform ion implantation processes in a manner such that the ions are directed into the channels of the crystalline structure, necessitating accurate alignment of the ion beam with the crystal lattice. For silicon workpieces, the orientation of the workpiece is well known. However, other workpieces may differ. For example, silicon carbide has a much more complex crystalline structure than silicon. In fact, silicon carbide may form a variety of different polytypes with different crystalline structures.

Additionally, the specifications that accompany SiC workpieces may be difficult to understand, complicating the identification of the orientation of the workpiece. Because of the conditions for crystal growth, the c-axis of a 4H SiC crystal is typically 4°+/−1° off from the normal to the surface of the workpiece and the direction of this tilt is not always obvious. The magnitude and direction of the tilt may also vary from one workpiece to the next and from one point on the workpiece to another. For this reason, process results may vary as the ion beam goes into and out of a channeling condition.

Therefore, it would be beneficial if there were an ion implanter and method of implanting ions into workpieces that could determine and monitor a crystalline orientation of a workpiece before ion implant treatment to facilitate channeling of the ion beam into the workpiece.

### SUMMARY

According to one embodiment, an ion implanter is disclosed. The ion implanter comprises an ion source to generate an ion beam; a platen to support a workpiece having a crystalline structure; an Xray source to generate an Xray beam, wherein at least a portion of the Xray beam impacts the workpiece to produce diffracted Xrays; an Xray detector positioned to receive the diffracted Xrays; and a controller, in communication with the Xray source, the platen, and the Xray detector. The controller comprises a memory device containing instructions, which when executed by the controller, enable the ion implanter to: perform a rocking curve test after the workpiece is disposed on the platen; and calculate an orientation of the platen for an ion implant process based on a result of the rocking curve test to facilitate channeling of the ion beam into the crystalline structure of the workpiece. In certain embodiments, the memory device further contains instructions, which when executed by the controller, enable the ion implanter to perform an ion implant process while the workpiece is disposed on the platen in the calculated orientation. In some embodiments, the rocking curve test is performed while the platen is disposed in a loading position, wherein a clamping surface of the platen is horizontal in the loading position. In some embodiments, the rocking curve test is performed at a plurality of locations on the workpiece. In certain embodiments, the workpiece is rotated about an axis through a center of the platen and perpendicular to a clamping surface of the platen such that the Xray beam impacts a new location on the workpiece. In certain embodiments, the ion beam has a width in an X direction and a height in a Y direction, and the platen is translated in the Y direction such that the Xray beam impacts a new location on the workpiece. In some embodiments, the platen is adapted to tilt about an X axis and a Y axis, wherein the X axis passes through a center of the platen and is parallel to a width of the ion beam, and the Y axis passes through the center of the platen and is parallel to a height of the ion beam, and wherein the rocking curve test is performed as the platen is tilted about the X axis to determine an X-tilt angle having a maximum intensity and is performed as the platen is tilted about the Y axis to determine a Y-tilt angle having a maximum intensity, and wherein the controller calculates an orientation to be used for the ion implant process based on the X-tilt angle and the Y-tilt angle determined during the rocking curve test. In certain embodiments, the Xray detector is a two dimensional array of sensors, such that an estimated X-tilt angle and an estimated Y-tilt angle are determined without tilting the workpiece and the rocking curve test is performed by tilting about the estimated X-tilt angle and the estimated Y-tilt angle. In some embodiments, the ion implanter comprises a collimator positioned to receive the Xray beam from the Xray source and to collimate the Xray beam to provide the portion of the Xray beam to the workpiece. In some embodiments, the platen, the Xray source and the Xray detector are disposed in a process chamber configured to receive the ion beam. In certain embodiments, the Xray source and the Xray detector are disposed on a top portion of the process chamber. In some embodiments, the platen is disposed in disposed in a process chamber configured to receive the ion beam and at least one of the Xray source and the Xray detector are disposed outside the process chamber, and a window is disposed in the process chamber to allow Xrays to pass between the process chamber and an environment outside the process chamber. In some embodiments, the Xray source and the Xray detector are movable so as to adjust an angle at which the Xray beam impacts the workpiece.

According to another embodiment, an ion implanter is disclosed. The ion implanter comprises an ion source to generate an ion beam; a process chamber, wherein the ion beam enters the process chamber, and a platen is disposed in the process chamber; an auxiliary chamber disposed proximate to the process chamber, containing: an auxiliary platen, adapted to support a workpiece having a crystalline structure; an Xray source to generate an Xray beam, wherein at least a portion of the Xray beam impacts the workpiece to produce diffracted Xrays; an Xray detector positioned to receive the diffracted Xrays; a workpiece handling robot to transfer workpieces from the auxiliary chamber to the process chamber; and a controller, in communication with the Xray source, the auxiliary platen, the Xray detector, the platen, and the workpiece handling robot, wherein the controller comprises a memory device containing instructions, which when executed by the controller, enable the ion implanter to: perform a rocking curve test after the workpiece is disposed on the auxiliary platen; calculate an orientation of the workpiece for an ion implant process based on a result of the rocking curve test to facilitate channeling of the ion beam into the crystalline structure of the workpiece; and transfer the workpiece to the platen in the process chamber using the workpiece handling robot. In some embodiments, the ion implanter comprises a second Xray source and a second Xray detector, wherein the memory device further contains instructions, which when executed by the controller, enable the ion implanter to perform a second rocking curve test in the process chamber using the second Xray source and the second Xray detector after the workpiece has been transferred to the process chamber. In certain embodiments, the second Xray source and the second Xray detector are disposed in the process chamber. In certain embodiments, the platen comprises a heater, and the memory device further contains instructions, which when executed by the controller, enable the ion implanter to: heat the platen after the workpiece is transferred to the process chamber; and perform the second rocking curve test in the process chamber using the second Xray source and the second Xray detector after the workpiece has reached a desired temperature. In certain embodiments, the second Xray source and the second Xray detector are disposed in the process chamber. In some embodiments, the Xray detector comprises a two dimensional array of sensors, such that an estimated X-tilt angle and an estimated Y-tilt angle are determined during the rocking curve test, and wherein a second rocking curve test is performed in the process chamber by tilting the platen about the estimated X-tilt angle and the estimated Y-tilt angle. In some embodiments, the memory device further contains instructions, which when executed by the controller, enable the ion implanter to perform an ion implant process while the workpiece is disposed on the platen in the calculated orientation.

According to another embodiment, a system is disclosed. The system comprises an ion implanter including an ion source to generate an ion beam; a process chamber comprising a platen to support a workpiece having a crystalline structure; an equipment front end module (EFEM) in communication with the process chamber via a load lock; an XRD station to perform a rocking curve test and determine an orientation information for the workpiece based on a result of the rocking curve test to facilitate channeling of the ion beam into the crystalline structure of the workpiece; a reader associated with the XRD station to detect an identifier, wherein the identifier is used to create a unique workpiece identifier; and a central controller in communication with the reader and the XRD station, so as to associate the orientation information from the XRD station with the unique workpiece identifier.

In some embodiments, the XRD station is located within the EFEM. In certain embodiments, the workpiece is disposed in a cassette, the cassette includes a cassette number which is the identifier, and a combination of cassette number and slot number is used to create the unique workpiece identifier, the reader determines a cassette number based on an RFID tag on the cassette and after receiving the cassette number from the reader, the central controller determines whether an XRD test has already been performed on the workpiece in the cassette. In certain embodiments, an atmospheric robot is disposed in the EFEM, and the central controller instructs the atmospheric robot to transfer the workpiece directly to the load lock if the XRD test has already been performed on the workpiece in the cassette. In certain embodiments, the central controller instructs the atmospheric robot to transfer the cassette to the XRD station if the XRD test has not been performed on the workpiece. In certain embodiments, the reader determines the unique workpiece identifier, and after receiving the unique workpiece identifier from the reader, the central controller determines whether an XRD test has already been performed on the workpiece. In certain embodiments, an atmospheric robot is disposed in the EFEM, and the central controller instructs the atmospheric robot to transfer the workpiece directly to the load lock if the XRD test has already been performed on the workpiece. In certain embodiments, the central controller instructs the atmospheric robot to transfer the workpiece to the XRD station if the XRD test has not been performed on the workpiece.

In some embodiments, the central controller directly or indirectly controls the platen based on the orientation information associated with the unique workpiece identifier.

In some embodiments, the XRD station is located outside the ion implanter, the EFEM and the process chamber. In certain embodiments, an additional reader is disposed in the EFEM or in the process chamber. In certain embodiments, after the rocking curve test is performed, the workpiece is transferred from the XRD station to the EFEM, the unique workpiece identifier is detected by the additional reader in the EFEM or in the process chamber, and transmitted to the central controller. In certain embodiments, if the central controller determines that a XRD process was already performed on the workpiece, the central controller directly or indirectly controls the platen based on the orientation information associated with the unique workpiece identifier. In certain embodiments, if the central controller determines that a XRD process was not already performed on the workpiece, the central controller reports an error. In certain embodiments, the workpiece is disposed in a cassette and the reader detects a cassette number and the cassette number is combined with a slot number to create the unique workpiece identifier, and, after the rocking curve test is performed on all workpiece in the cassette, the cassette is transferred from the XRD station to the EFEM, the unique workpiece identifier is detected by the additional reader in the EFEM or in the process chamber, and transmitted to the central controller. In certain embodiments, a second XRD station is located outside the EFEM and the process chamber; a second reader is associated with the second XRD station to determine a unique workpiece identifier; and the central controller in communication with the second reader and the second XRD station, so as to receive the unique workpiece identifier and associate orientation information with that unique workpiece identifier.

According to another embodiment, a system is disclosed. The system comprises an ion implanter including an ion source to generate an ion beam; a process chamber comprising a platen to support a workpiece having a crystalline structure; an equipment front end module (EFEM) in communication with the process chamber via a load lock; an XRD station to perform a rocking curve test and determine an orientation information for the workpiece based on a result of the rocking curve test to facilitate channeling of the ion beam into the crystalline structure of the workpiece, wherein the XRD station is not located in the EFEM or the process chamber; and a controller in communication with the XRD station, so as to receive the orientation information from the XRD station and directly or indirectly control the platen based on the orientation information. In some embodiments, a second controller is dedicated to the ion implanter, and the controller forwards orientation information to the second controller to control the platen. In some embodiments, a second XRD station is located outside the EFEM and the process chamber; and the controller in communication with the second XRD station, so as to receive the orientation information from the second XRD station.

According to another embodiment, a system is disclosed. The system comprises an ion implanter including an ion source to generate an ion beam; a process chamber comprising a platen to support a workpiece having a crystalline structure; a reader; and a controller in communication with the reader, wherein the controller comprises a table or other data structure that correlates unique workpiece identifier with orientation information, and wherein the controller receives the unique workpiece identifier from the reader, associates the orientation information with the unique workpiece identifier and directly or indirectly controls the platen based on the orientation information. In some embodiments, the system comprises a second controller dedicated to the ion implanter, wherein the controller forwards orientation information to the second controller to control the platen. In some embodiments, the system comprises an equipment front end module (EFEM) in communication with the process chamber via a load lock; and the reader is disposed in the EFEM or the process chamber

### BRIEF DESCRIPTION OF THE FIGURES

For a better understanding of the present disclosure, reference is made to the accompanying drawings, which are incorporated herein by reference and in which:

FIG. 1 shows an ion implanter according to one embodiment;

FIG. 2A shows one configuration of the Xray source and Xray detector in the process chamber;

FIG. 2B shows another configuration of the Xray source and Xray detector in the process chamber;

FIG. 2C shows a third configuration of the Xray source and Xray detector in the process chamber;

FIG. 2D shows a configuration of the Xray source and Xray detector outside the process chamber;

FIG. 3 shows rotation and tilt of a workpiece on the platen;

FIG. 4 shows an Xray source and collimator according to one embodiment;

FIG. 5 shows one sequence that may be used to process workpieces using the ion implanter of FIG. 1;

FIG. 6 shows one embodiment of a rocking curve test that may be performed using the ion implanter of FIG. 1;

FIG. 7 shows an ion implanter according to another embodiment;

FIG. 8 shows one sequence that may be used to process workpieces using the ion implanter of FIG. 7;

FIG. 9 shows the configuration of a XRD station according to one embodiment;

FIG. 10 shows a system with an XRD station disposed in the EFEM;

FIG. 11 shows a sequence used to identify a workpiece and then orient the platen using the configuration of FIG. 10;

FIG. 12 shows a system with one or more XRD stations disposed outside the ion implanter, the EFEM and the process chamber according to one embodiment;

FIG. 13 shows a sequence used to identify a workpiece and then orient the platen using the configuration of FIG. 12; and

FIG. 14 shows a system with one or more XRD stations disposed outside the ion implanter, the EFEM and the process chamber according to another embodiment.

### DETAILED DESCRIPTION

As earlier noted, performing a channeled implant may be beneficial in some instances. The term “channeled implant” refers to an implant that is performed such that the ions are implanted along the channels of the crystalline structure of a workpiece, such as a SiC wafer. However, correctly orienting the workpiece such that the incoming ion beam is aligned with the channels may be difficult. The precision of this alignment depends on several parameters, but most notably on the energy of the ions, with effective channeling using a maximum angle deviation that decreases h with increasing energy. The critical angle for channeling is given by

$$ψ = \sqrt{\frac{U ( {r}_{crit} )}{E}}$$

where ψ is the critical angle, U(r_{crit}) is the potential energy of the channel wall determined by the crystal lattice, and E is kinetic energy of the ion. For high energy implants of several MeV, the angular acceptance of the channel may be as small as 0.05°, while at a few keV it may be several degrees.

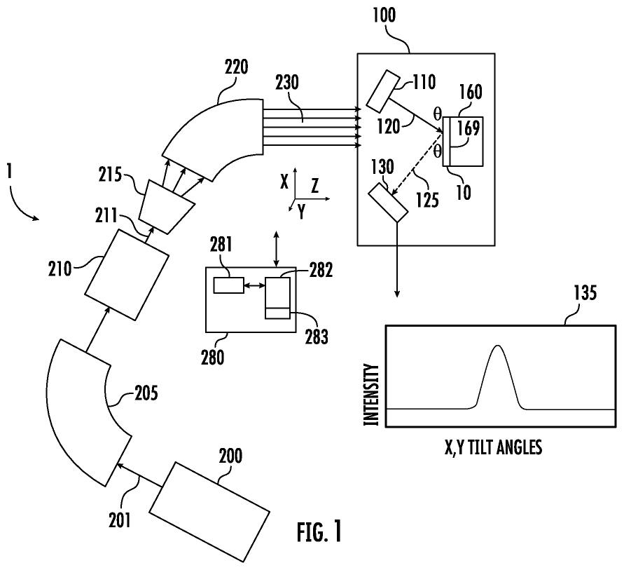

FIG. 1 shows a first embodiment of an ion implanter 1 that is capable of performing angular alignment and verification using XRD prior to performing an implant.

In some embodiments, the ion implanter 1 may be a high energy or medium current beamline ion implanter, capable of generating implant energies of 1 MeV or more. In other embodiments, the implant energies generated by the ion implanter 1 may be less than 1 MeV. The ion implanter 1 includes an ion source 200, which is used to generate an extracted ion beam 201. In one embodiment, the ion source 200 may be a Bernas or indirectly heated cathode (IHC) ion source. Of course, other types of ion sources may also be employed. A feedgas is supplied to the ion source 200, which is then energized to generate ions. Extraction optics (not illustrated) are then used to extract these ions from the ion source 200 and form them into an extracted ion beam 201.

The extracted ion beam 201 may be directed toward a mass analyzer 205, which only allows the passage of certain species of ions. The ions that exit the mass analyzer 205 are directed toward the accelerator component 210. The accelerator component 210 serves to accelerate the ions that enter the component from a lower energy to a higher energy. The accelerator component 210 may have different configurations.

In one embodiment, the accelerator component 210 may be an acceleration column, comprising a plurality of biased electrodes that serve to accelerate the ion beam. The electrodes may become more negatively biased as the ions pass through the column, accelerating the positive ions.

In another embodiment, the accelerator component 210 may be a tandem accelerator. In this embodiment, negative ions may be accepted into a first accelerator column and accelerated to a first energy, then stripped of electrons to create positive ions and accelerated by a second accelerator column to a final higher energy.

In another embodiment, the accelerator component 210 may be a linear accelerator (LINAC). In this embodiment, a separate buncher may accept the ion beam from the ion source 200 and generate a pulsed ion beam that is bunched. A series of resonators or accelerators may be excited by respective RF signals to increasing accelerate the incoming pulsed beam to a desired high energy level.

In all of these embodiments, after exiting the accelerator component 210, the spot shaped ion beam 211 may enter a scanner 215. The scanner 215 causes the spot shaped ion beam 211 to be fanned out into a plurality of divergent ion beamlets. In other words, the scanner 215 creates diverging ion trajectory paths. The scanner 215 may be electrostatic or magnetic. The ion beam is made wider by the use of the scanner 215. The direction in which the scanner 215 moves the beam may be referred to as the X direction. Note that exiting the scanner 215, the ion beam is much wider than it is tall.

Angle corrector 220 is designed to deflect ions in the scanned ion beam to produce ion beam 230 having parallel ion trajectories, thus focusing the scanned ion beam. Specifically, the angle corrector 220 is used to alter the diverging ion trajectory paths into substantially parallel paths of the ion beam 230. In some embodiments, angle corrector 220 may comprise magnetic pole pieces which are spaced apart to define a gap and a magnet coil which is coupled to a power supply. The scanned ion beam passes through the gap between the magnetic pole pieces and is deflected in accordance with the magnetic field in the gap. In other embodiments, the angle corrector 220 may be an electrostatic lens sometimes referred to as a parallelizing lens.

Of course, the ion implanter may include other components, such as quadrupole lenses, additional electrodes to accelerate or decelerate the beam and other elements.

The ion beam 230 enters the process chamber 100. In FIG. 1, a top view of the ion implanter 1 is shown, such that the height of the ion beam 230 is perpendicular to the plane of the page. A Cartesian Coordinate System may be defined to aid in the explanation, where the Z direction is defined by the path of the ion beam 230. The ion beam 230 has a height in the Y direction and a width in the X direction, as illustrated in FIG. 1.

As shown in FIG. 1, the ion beam 230 enters a process chamber 100, where the workpiece to be implanted is disposed. The workpiece 10 is disposed on a clamping surface 169 of a platen 160. The platen 160 may be capable of movement and rotations in several directions. In FIG. 1, the platen 160 is in an operational, or implant position, where the clamping surface 169 of the platen 160 is roughly perpendicular to the ion beam 230. This is the orientation of the platen 160 during ion implanting. In this embodiment, an Xray source 110 and an Xray detector 130 are disposed on either side of the platen 160 in the X or width direction.

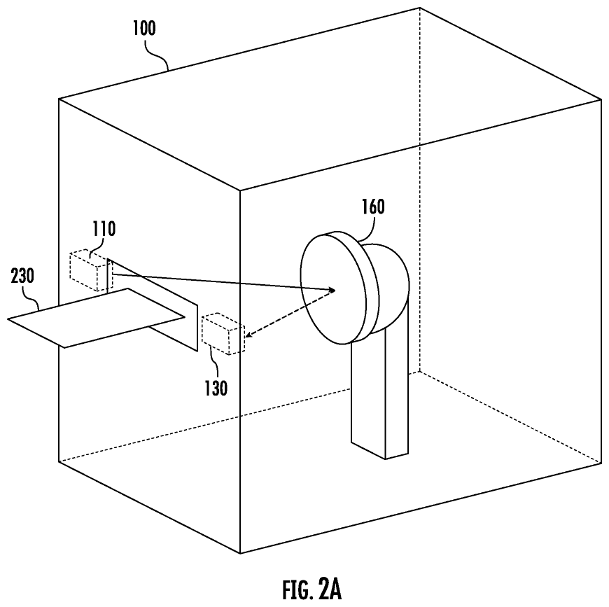

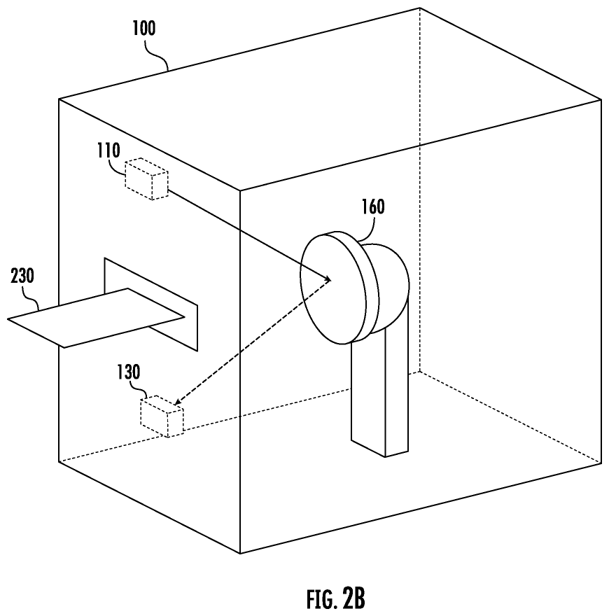

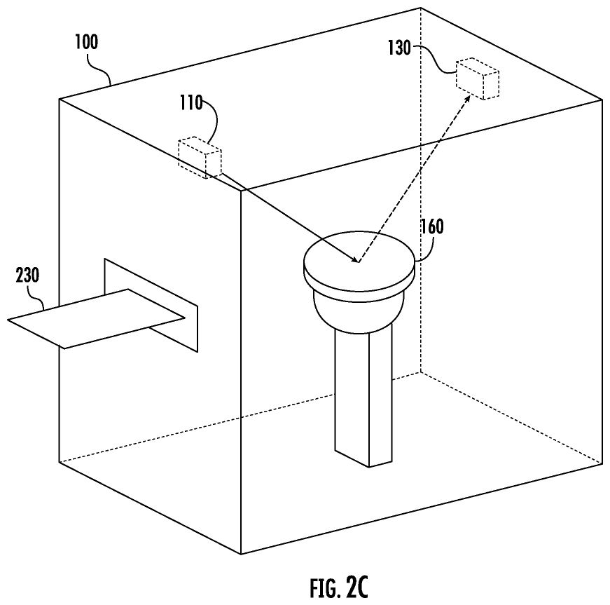

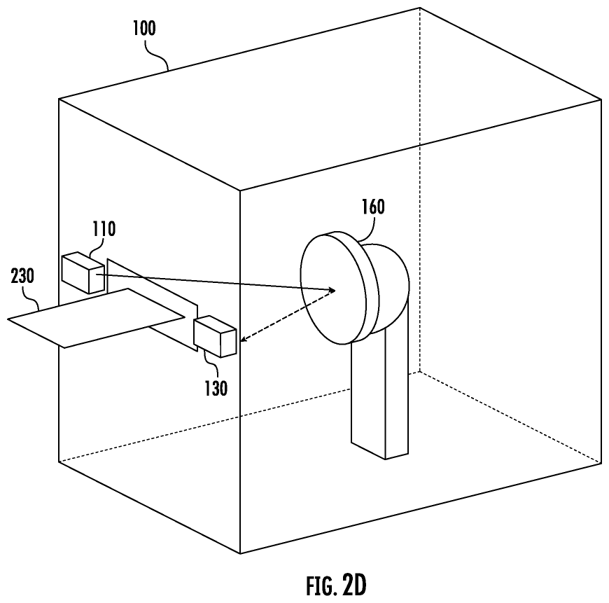

A perspective view of the process chamber 100 is shown in FIG. 2A, where the Xray source 110 and the Xray detector 130 are positioned in the process chamber 100 and disposed on either side of the platen 160 in the X direction.

However, other embodiments are also possible. FIG. 2B shows a perspective view of the process chamber 100 according to another embodiment. In this embodiment, the Xray source 110 and the Xray detector 130 are positioned in the process chamber 100 and disposed on either side of the platen 160 in the Y or height direction.

The workpiece 10 may be moved in one or more dimensions by the platen 160. For example, the platen 160 may move in the Y direction (which corresponds to the height of the ion beam 230) so that, after the platen 160 has moved through the ion beam 230, the entire workpiece 10 is exposed to the ion beam 230. The platen 160 is also capable of tilting and rotation about several axis.

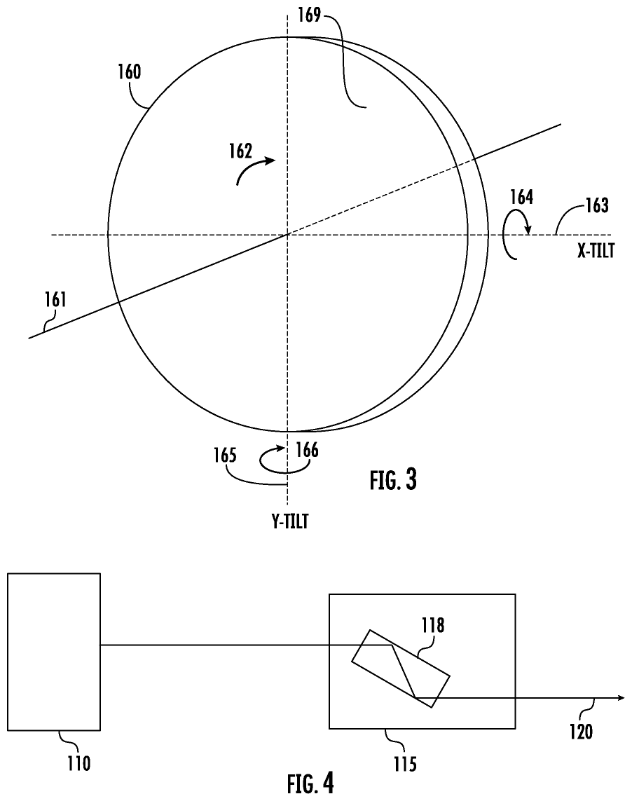

FIG. 3 shows the platen 160 and its various directions of rotation. FIG. 3 shows a perspective view of the platen 160 that is capable of rotation, referred to as a roplat. The platen 160 may have three axes. There may be a twist axis 161, which is perpendicular to the clamping surface 169 of the platen 160 and passes through the center of the platen 160. Rotation about this twist axis 161 is referred to a twist angle 162. There is an X axis 163 that passes through the center of the platen, is parallel to the clamping surface 169 of the platen 160 and is perpendicular to the twist axis 161. The X axis 163 is parallel to the wide dimension of the ion beam 230. Tilting about the X axis 163 is referred to as an X-tilt angle 164. There is also a Y axis 165 that also passes through the center of the platen 160, is parallel to the clamping surface 169 of the platen 160 and is perpendicular to the twist axis 161 and the X axis 163. Tilting about the Y axis 165 is referred to as a Y-tilt angle 166.

Also disposed in the process chamber 100 is the Xray source 110 and the Xray detector 130. As shown in FIG. 4, a collimator 115 may also be used to accept the Xray beam from the Xray source 110 to provide collimation of the Xrays and form an emitted Xray beam 120. In some embodiments, the Xray source 110 may be a filtered Cu target Xray source, as is known in the art, or any other suitable Xray source. The collimator 115 may be used to produce tightly parallel beams that may be directed towards particular regions of the workpiece 10. In some embodiments, the collimator 115 comprises one or more slits. In other embodiments, the collimator 115 comprises one or more crystals, such as germanium or silicon crystals. In one embodiment, shown in FIG. 4, the Xray beam from the Xray source 110 enters a germanium crystal 118 through one face, and reflects off two interior faces along the (220) direction before exiting the crystal as the emitted Xray beam 120. This may be referred to as a Ge (220)-2 bounce collimator or monochromator. In another embodiment, two crystals are disposed such that when the Xrays exit the first germanium crystal, they enter the second germanium crystal and are again reflected off the two interior faces along the (220) direction before exiting as the emitted Xray beam 120. This may be referred to as a Ge (220)-4 bounce collimator or monochromator. In another embodiment, the crystal may be disposed such that the Xray beam from the Xray source 110 enters one face and is reflected off two interior faces along the (440) direction. The Xrays then exit a first germanium crystal and enter a second germanium crystal, where they are again reflected off two interior faces in the (440) direction before exiting as the emitted Xray beam 120. This may be referred to as a Ge (440)-4 bounce collimator or monochromator. Of course, other collimators may be used. When crystals are employed, only the Xray beams having the desired trajectory are able to pass through the crystals and reach the workpiece 10. In each of these embodiments, the Xray source 110 generates an Xray beam wherein at least a portion of that Xray beam ultimately strikes the workpiece 10 as emitted Xray beam 120.

The Xray detector 130 measures the diffracted Xrays 125 from the workpiece and may be used to plot the detected amount of diffracted Xrays 125, also referred to as intensity, as a function of X-tilt and Y-tilt angles, as shown in graph 135 of FIG. 1. Xray detectors 130 are well known and, as such, are not described in more detail herein. In some embodiments, the Xray source 110, the workpiece 10 and the Xray detector 130 are arranged to achieve the Bragg scattering angle, given by the Bragg equation:

λ=2d sin θ
where λ is the wavelength of the Xray (0.1541 nm for a Cu K_{α} Xray), d is the spacing of the crystal planes; for 4H SiC in the (0001) direction, the selection rules allow the (0004) planes to give a spacing of c/4=0.251 nm, giving

$$θ = arc sin ( \frac{λ}{2 d} ) = 17.8 ° .$$

For Xray beams of a different wavelength or workpieces of a different material, the Xray source 110 and the Xray detector 130 may be positioned at different angles. Note that both the Xray source 110 and the Xray detector 130 are positioned at the same angle relative to the workpiece 10.

In another embodiment, the Xray source and the Xray detector are mounted on articulated arms so that they can be used for different diffraction angles for different crystal lattice spacings.

In another embodiment, the Xray detector 130 may be either a one or two dimensional array of sensors, that may be used to enable detection of a range of Xray diffraction angles. In these embodiments, the Xray detector 130 comprises a plurality of sensors, where each sensor is adapted to detect Xrays. This one or two dimensional Xray detector may be referred to as an extended Xray detector. In this way, rather than only receiving information about a single angle, this extended Xray detector is able to provide information about a plurality of angles at the same time.

A controller 280 is also used to control the ion implanter 1. The controller 280 has a processing unit 281 and an associated memory device 282. This memory device 282 contains the instructions 283, which, when executed by the processing unit 281, enable the system to perform the functions described herein. The controller 280 is able to control the twist angle 162, the X-tilt angle 164 and Y-tilt angle 166 of the platen 160. The controller 280 is also in communication with the components of the ion implanter 1 including the Xray source 110 and the Xray detector 130. This memory device 282 may be any non-transitory storage medium, including a non-volatile memory, such as a FLASH ROM, an electrically erasable ROM or other suitable devices. In other embodiments, the memory device 282 may be a volatile memory, such as a RAM or DRAM. In certain embodiments, the controller 280 may be a general purpose computer, an embedded processor, or a specially designed microcontroller. The actual implementation of the controller 280 is not limited by this disclosure.

Having described one configuration of the ion implanter 1, the operation of the system will be described.

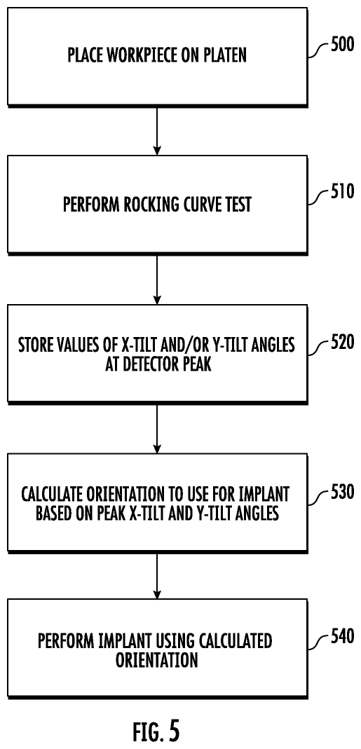

One mode of operation is shown in FIG. 5. As shown in Box 500 of FIG. 5, the workpiece 10 is disposed on the clamping surface 169 of the platen 160 in the process chamber 100. The platen 160 is disposed in its operational position. The controller 280 may then use the Xray source 110, the Xray detector 130 and the platen 160 perform a rocking curve test, as shown in Box 510. As is well known, a rocking curve test is used with XRD to identify an orientation of the crystalline structure of a workpiece. Specifically, a rocking curve test varies the angle of a workpiece while an Xray beam impacts the workpiece. The Xrays are diffracted and are received by an Xray detector. The angle of the workpiece that results in the greatest intensity of diffracted Xrays is the direction of maximum channeling. A rocking test may be performed in one direction or in two directions, e.g., by tilting the workpiece about the X axis 163 and/or by tilting the workpiece about the Y axis 165.

The controller 280 may then store the X-tilt angle and the Y-tilt angle that resulted in the peak intensity, as shown in Box 520. Based on this information, the controller 280 may determine the crystalline orientation of the workpiece 10, and consequently, the proper orientation of the workpiece 10 during the subsequent implant, as shown in Box 530. For example, SiC is available in a plurality of different polytypes, including 2H, 4H, 6H, 15R and 3C. Each polytype may utilize a different optimal set of tilt angles. By performing the rocking curve test, the controller 280 may identify the polytype and also the exact orientation of the workpiece. Once the X-tilt and Y-tilt angles are calculated, these calculated angles may be used during the ion implantation process, as shown in Box 540.

In the embodiment shown in FIG. 2A, with the ion beam 230 exactly in the Z direction and the Xray source 110 and Xray detector 130 symmetrically angled about the Z direction, the optimum channeling will be at the workpiece angle where the Xray diffraction intensity is maximized. Several eventualities may alter this simple algorithm. For example, if precision measurement of the ion beam 230 shows that it is slightly angled with respect to the Z axis, or if the Xray source 110 or Xray detector 130 is displaced from its ideal position due to mechanical tolerances, these shifts will need to be taken into account by displacing the implant angle from the angle of maximum diffraction intensity.

By determining the X-tilt and Y-tilt angles where the intensities of the Xray emissions are greatest, the controller 280 may identify the appropriate orientation of the platen 160 to be used for the process to implant facilitate channeling. Specifically, in some embodiments, it may be desirable to perform the implant when the workpiece is oriented on the platen 160 such that the implant is a channeled implant. This allows the implanted ions to be implanted deeper (for a given energy) and also causes less damage to the workpiece. In some embodiments, the X-tilt angle and Y-tilt angle are selected to maximize channeling.

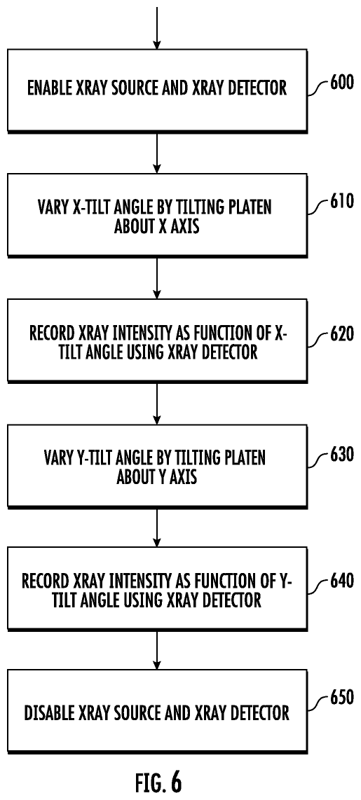

FIG. 6 shows one sequence that may be used to perform the rocking curve test. First, as shown in Box 600, the Xray source 110 and the Xray detector 130 are enabled. The controller 280 then varies the X-tilt angle 164 of the platen 160 while the emitted Xray beam 120 is directed at the workpiece 10, as shown in Box 610. The range of X-tilt angles used during the rocking curve test may vary. For example, in some embodiments, the workpiece may be tilted ±5°. In other embodiments, the range or angles may be smaller such as ±1° or ±2°. In yet other embodiments, the range of angles may be larger than 5°. The Xray detector 130 is used to record the intensity of the diffracted Xrays 125 and the controller 280 saves these recorded intensities as a function of X-tilt angle, as shown in Box 620. The result of this process may be a graph 135, as shown in FIG. 1 or may be a table of values. The controller 280 then varies the Y-tilt angle 166 of the platen 160 while the emitted Xray beam 120 is directed at the workpiece 10, as shown in Box 630. In some embodiments, the X-tilt angle is set to the X-tilt angle that exhibits the largest intensity. Again, the range of Y-tilt angles that are used during the rocking curve test may vary, as described above. The Xray detector 130 is used to record the intensity of the diffracted Xrays 125 and the controller 280 saves these recorded intensities as a function of Y-tilt angle, as shown in Box 640. The result of this process may be a second graph 135, as shown in FIG. 1 or may be one or more tables, each including values of tilt angles and the corresponding intensities. Once this is complete, the controller 280 may disable the Xray source 110 and the Xray detector 130. Note that in some embodiments, the rocking curve test is only performed for one tilt angle. For example, in some embodiments, Boxes 610-620 or Boxes 630-640 may be omitted.

In yet other embodiments, if an extended Xray detector is used, the variation of the X-tilt and Y-tilt angles may be smaller. For example, a two dimensional Xray detector may allow the controller 280 to determine the X-tilt and Y-tilt angles that exhibited the highest intensity without rotating the workpiece. In another embodiment where an extended Xray detector is used, the initial output from the extended Xray detector is used to set the estimated X-tilt and Y-tilt angles and the rocking curve test is then performed, tilting the platen about these estimated angles. For example, the initial scan may indicate that the maximum intensity was detected at tilt angles X1 and Y1. The rocking curve test may then be performed, for example, using X-tilt and Y-tilt angles of X1±1° and Y1±1°, respectively.

In some embodiments, it may be beneficial to perform the rocking curve test at a plurality of locations on the workpiece. This may be achieved in a plurality of ways. In one embodiment, the platen 160 may be moved in the Y direction to allow the emitted Xray beam 120 to strike a different location on the workpiece. In another embodiment, the platen 160 may rotate about the twist axis 161 to allow the emitted Xray beam 120 to strike a different location on the workpiece. In another embodiment, the platen 160 is moved in the Y direction and rotated about the twist axis 161. In each of these embodiments, once the workpiece 10 has been moved or rotated, the sequence shown in FIG. 6 may be repeated. In some embodiments, the results from the plurality of rocking curve tests may be averaged to determine the appropriate X-tilt and Y-tilt angles for the implant process. In other embodiments, the X-tilt and Y-tilt angles may vary as a function of the position of the platen 160 in the Y direction. For example, if the X-tilt angle and/or Y-tilt angle vary along the Y direction, the tilt of the platen 160 may be varied as the ion beam 230 is scanning the workpiece 10. If the X-tilt angle and/or the Y-tilt angle vary along the X axis, the angle corrector 220 may be adjusted to produce a converging or diverging ion beam to address a Y-tilt variation while a rotation of the scan plates may be adjusted to produce a twist in the trajectories to address an X-tilt variation.

In some embodiments, the platen 160 may also heat the workpiece 10 to an elevated temperature, such as greater than 350° C. In some embodiments, the elevated temperature may be 500° C. or more. In these embodiments, the rocking curve test may not commence until the workpiece 10 reaches the desired temperature.

In other embodiments, the rocking curve test may be performed before the workpiece is heated and then again after it is heated. In this way, any change in the rocking curve test results may be the result of thermal warping or distortion of the workpiece. This may be compensated for by additional clamping force (either electrostatic or mechanical). Alternatively, the orientation of the platen 160 may be adjusted to achieve the best compromise for the shape of the workpiece at the implant temperature.

While FIGS. 1 and 2A-2B show the rocking curve test being performed while the platen 160 is in the operational position, other embodiments are also possible. FIG. 2C shows a perspective view of the process chamber 100. In this embodiment, the platen 160 is disposed in the loading position, wherein the clamping surface of the platen 160 is horizontal. In this embodiment, the Xray source 110 and the Xray detector 130 are disposed inside the process chamber 100 and near a top portion of the process chamber 100. The area near the top of the process chamber 100 may have less contaminants than other areas. In this embodiment, the X-tilt angle is set to 90° to place the platen 160 in the loading position. The X-tilt angle is then varied about this tilt angle. In other words, while the embodiments of FIGS. 1 and 2A-2B vary the X-tilt angle about 0°, the embodiment of FIG. 2C varies the X-tilt angle about 90°.

In yet another embodiment, at least one of the Xray source 110 or the Xray detector 130 may be disposed outside the process chamber 100, as shown in FIG. 2D. For example, windows may be disposed in the walls of the process chamber 100, such that the Xrays may pass through the window. In one embodiment, the Xray source 110 and the Xray detector 130 are both disposed outside the process chamber 100. In this embodiment, Xrays exiting the Xray source 110 pass through a first window and into the process chamber 100 where they impact the workpiece 10. The diffracted Xrays then pass through a second window to the Xray detector 130. In some embodiments, the windows may be a thin polymer film, a diamond like carbon window or a beryllium window. The Xray source 110 and/or the Xray detector 130 may be positioned as shown in FIG. 2D, or may be positioned above the top surface of the process chamber 100.

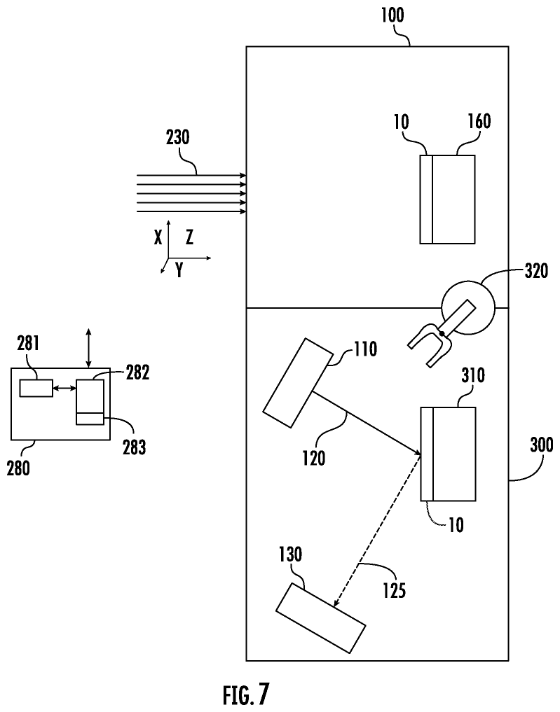

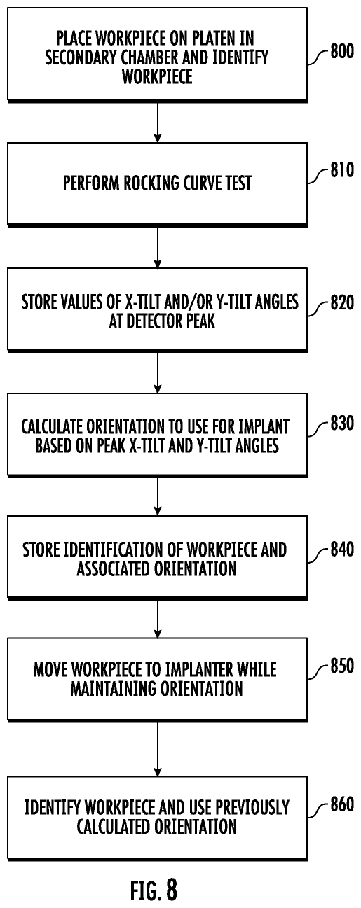

In certain embodiments, the rocking curve test may be performed in a chamber different from the process chamber. One such embodiment is shown in FIG. 7. Though not shown, the ion implanter 1 may include the ion source 200, the mass analyzer 205, the accelerator component 210, the scanner 215 and the angle corrector 220.

In this embodiment, the Xray source 110, and the Xray detector 130 are disposed in an auxiliary chamber 300. An auxiliary platen 310 is also disposed in the auxiliary chamber 300. This auxiliary platen 310 may be similar to the platen 160 described above, in that it is capable of rotation about one or more axes.

In this way, the rocking curve test may be performed in the auxiliary chamber 300. This may allow higher throughput, as the process chamber 100 is not used for the rocking curve test. Thus, in this embodiment, the rocking curve test is performed in the auxiliary chamber 300 and a workpiece handling robot 320 is used to move the workpiece to the process chamber 100. The rocking curve test may be performed while the clamping surface of the auxiliary platen 310 is vertical, as shown in FIG. 7. In other embodiments, the rocking curve test may be performed while the clamping surface of the auxiliary platen 310 is horizontal, similar to the embodiment shown in FIG. 2C. A sequence showing the operations associated with this embodiment is shown in FIG. 8.

As shown in Box 800, the workpiece is placed on the clamping surface of the auxiliary platen 310 in the auxiliary chamber 300. An identification of the workpiece is performed. In Box 810, the controller 280 then performs a rocking curve test, as described with respect to FIG. 6. The controller 280 stored the X-tilt and Y-tilt angles at which the detected intensities were at a peak, as shown in Box 820. These tilt angles may then be used to calculate the orientation to be used during a subsequent ion implantation process, as shown in Box 830. The controller 280 then stores the identity of the workpiece and the orientation associated with that workpiece, as shown in Box 840. The controller 280 then utilizes the workpiece handling robot 320 to move the workpiece to the process chamber 100, while maintaining its orientation, as shown in Box 850. Once in the process chamber 100, the controller 280 identifies the workpiece and then uses the calculated orientation (i.e., the X-tilt and Y-tilt angles) associated with that workpiece for the ion implant process, as shown in Box 860. This approach minimizes the time that the workpiece remains in the process chamber 100, increasing throughput.

In some embodiments, the controller may store the X-tilt and Y-tilt angles from Box 830 and not calculate the orientation to be used for the implant process until a later time.

In yet another embodiment, the Xray source 110 and the Xray detector 130 may be duplicated, such that there is an Xray source 110 in the auxiliary chamber 300 and in the process chamber 100. Similarly, there may be an Xray detector 130 in the auxiliary chamber 300 and the process chamber 100. In this embodiment, the rocking curve test may be performed in the auxiliary chamber 300. After the workpiece is moved to the process chamber 100, it may be heated. The change in temperature may affect the orientation for the ion implant process. Thus, after being heated, a second rocking curve test may be repeated. However, since a preliminary rocking curve test was already performed in the auxiliary chamber 300, the range of angles used in the second rocking curve test may be smaller, allowing the test to be completed more quickly.

In one embodiment, an extended Xray detector may be disposed in the auxiliary chamber 300 and the estimated X-tilt and Y-tilt angles may be determined without tilting the workpiece. These estimated X-tilt and Y-tilt angles are then used as the center of the rocking curve test that is performed in the process chamber 100.

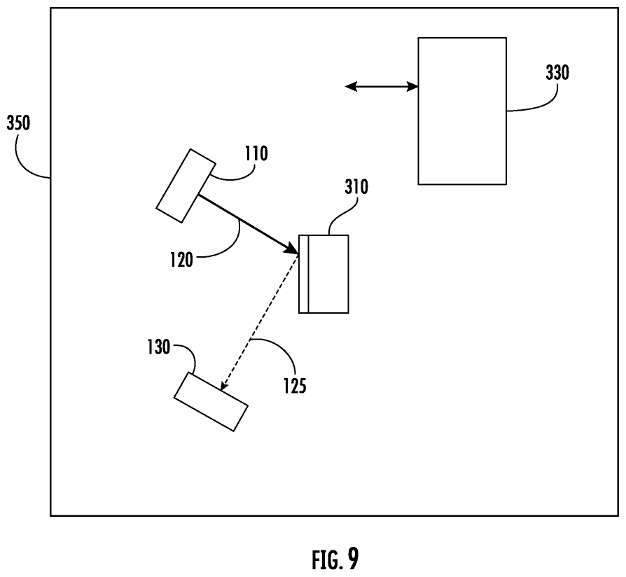

The components in the auxiliary chamber 300 may form part of an XRD station. In some embodiments, such as that shown in FIG. 9, an XRD station 350 includes an Xray source 110 to generate an emitted Xray beam 120, an Xray detector 130 to receive the diffracted Xrays 125, and an auxiliary platen 310. The XRD station 350 also includes an XRD controller 330 that is used to perform the rocking curve test and store the results. This XRD controller 330 is configured to perform a rocking curve test, such as that shown in FIG. 6. The XRD controller 330 is in communication with the auxiliary platen 310, the Xray source 110 and the Xray detector 130 so as to perform the rocking curve test. Additionally, the XRD controller 330 may also include a network interface, allowing it to communicate with other devices, such as a central controller, which may be controller 280 or a different controller.

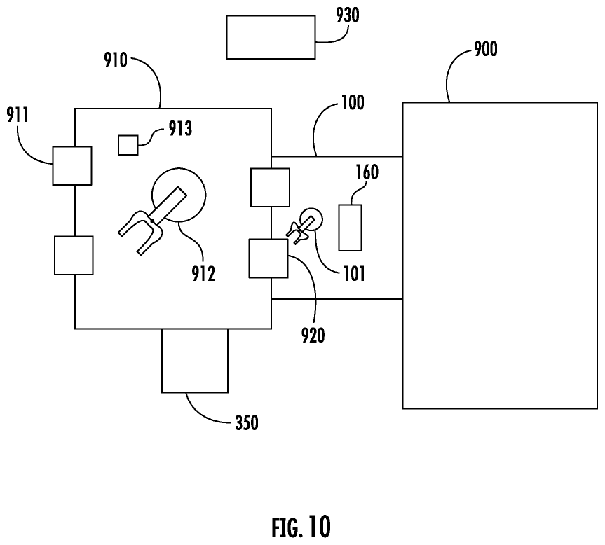

In addition to the configurations already discussed, this XRD station 350 may be disposed in other locations within the system. FIG. 10 shows a first configuration where the XRD station 350 is located in or near the Equipment Front End Module (EFEM). FIG. 10 shows an ion implanter 900, which may include many of the components described with respect to FIG. 1. The ion implanter 900 may include the ion source 200, the mass analyzer 205, the accelerator component 210, the scanner 215 and the angle corrector 220, which are shown in FIG. 1. The system also includes the process chamber 100 in which the platen 160 is disposed. The ion beam generated by the ion implanter 900 is directed to the process chamber 100. Workpieces are loaded into the process chamber 100 through a loading station, also referred to as an EFEM 910. The EFEM 910 includes one or more transfer stations 911, which transfer workpieces from the exterior environment into the EFEM 910. These transfer stations 911 may accept a cassette, which includes a plurality of workpieces, each disposed in a respective slot. One or more load locks 920 separate the EFEM 910 from the process chamber 100. The EFEM 910 also includes one or more atmospheric robots 912, which are used to transfer workpieces to be processed from the transfer stations 911 to the load locks 920 and return processed workpieces from the load locks 920 to the transfer stations 911. The XRD station 350 is located within the EFEM 910 or adjacent to the EFEM 910 such that the atmospheric robots 912 can access the XRD station 350. Additionally, a reader 913 may be disposed in the EFEM 910. This reader 913 is used to detect a unique workpiece identifier, such as a serial number or other indicia, so as to uniquely identify each workpiece. In certain embodiments, the cassette includes an RFID tag. The reader 913, which may be an RFID reader located within the transfer station 911, is able to read the RFID tag to uniquely identify the cassette. In some embodiments, this cassette identifier, in conjunction with the slot number in which the workpiece is disposed, forms the unique workpiece identifier. In other embodiments, a serial number is etched or otherwise affixed to each workpiece. In this embodiment, the reader 913 may be an OCR (optical character recognition) reader which may be used to read the serial number from the workpiece. Of course, the unique workpiece identifier may be created in other ways.

Further, a central controller 930 may be used to monitor the transfer of workpieces. This central controller 930 also tracks the results of the XRD process for each workpiece. In some embodiments, this central controller 930 also controls the ion implanter 900. However, in other embodiments, the controller 280 that controls the ion implanter 900 and the central controller 930 may be different components.

The central controller 930 may create a table or other data structure that includes the unique workpiece identifier, which may be a combination of cassette number and slot number, or a serial number, as well as the desired orientation of that workpiece, as determined by the XRD station 350. This table or other data structure may be disposed in a memory device located within the central controller 930.

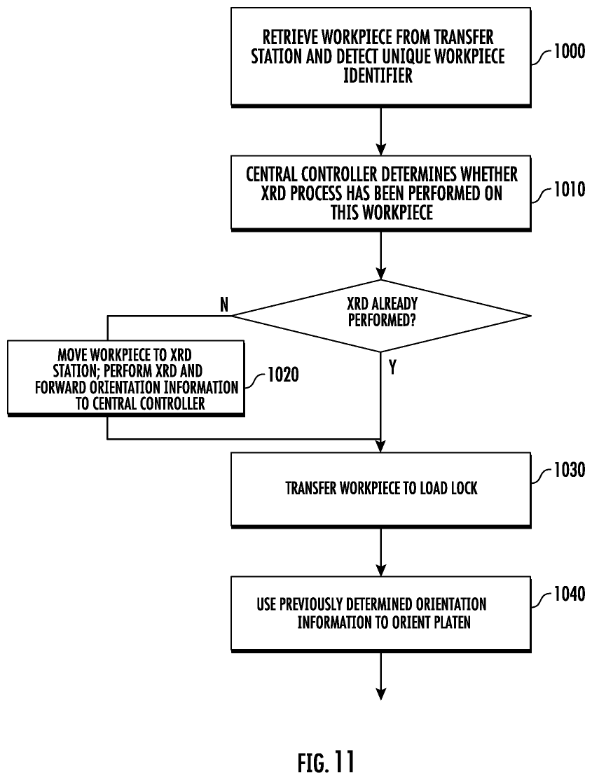

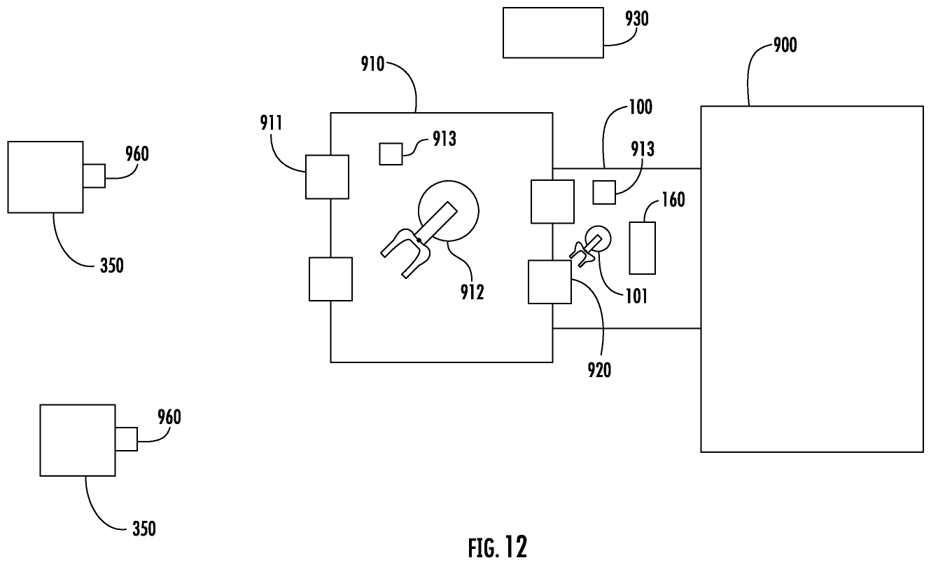

Using this unique workpiece identifier and the results from the XRD station 350, the central controller 930 can control the flow and processing of workpieces in the ion implanter 900. This sequence is shown in FIG. 11. First, a workpiece is placed in the transfer station 911. The workpiece may be disposed within a slot of a cassette. The reader 913 is used to detect an identifier, such as the unique workpiece identifier, as shown in Box 1000. In some embodiments, this may be done by combining the cassette identifier and the slot number, or by reading the serial number on the workpiece. This information is then forwarded to the central controller 930. The central controller 930 checks whether the orientation of this workpiece has already been performed, as shown in Box 1010. This may be done by comparing the unique workpiece identifier that was determined by the reader 913 to a table of workpieces that have already been processed by the XRD station 350. If the central controller 930 determines that the workpiece has not been processed by the XRD station 350, it instructs the atmospheric robot 912 to move the workpiece to the XRD station 350, as shown in Box 1020. In some embodiments, the entire cassette is moved to the XRD station 350. In other embodiments, the workpieces are transferred one at a time. The XRD station 350 then performs the rocking curve test and once the XRD process is complete, the XRD controller 330 forwards the orientation information to the central controller 930, which correlates the unique workpiece identifier with this orientation information. The atmospheric robot 912 then transfers the workpiece from the XRD station 350 to the load lock 920, as shown in Box 1030. If the central controller 930 determines that the workpiece has already been processed by the XRD station 350, it instructs the atmospheric robot to move the workpiece directly to the load lock 920, bypassing the XRD station 350, as shown in Box 1030. Once the workpiece enters the process chamber 100, the vacuum robot 101 moves the workpiece to the platen 160. The central controller 930 then retrieves the orientation information associated with this workpiece from the table or other data structure and either directly controls the platen 160, or forwards that orientation information to the controller 280, which then controls the platen 160, as shown in Box 1040. After this, the ion implanter 900 is enabled so that the implantation may be performed.

In another embodiment, the cassette number is sufficient to perform the sequence shown in FIG. 11. This embodiment assumes that all workpieces within a cassette are processed in the same manner. Specifically, in Box 1000, the reader 913 reads the RFID tag on the cassette and treats this as the identifier. This identifier is then forwarded to the central controller 930. Then, in Box 1010, the central controller 930 determines whether the XRD process has been performed on the workpieces contained in this cassette. If not, the entire cassette is transferred to the XRD station 350, as shown in Box 1020. The XRD station 350 may then perform the rocking curve test on each workpiece and once the XRD process is complete, the XRD controller 330 forwards the orientation information to the central controller 930, which correlates the unique workpiece identifier (in the form of cassette number and slot number) with this orientation information and saves the information in a table or other data structure. In some embodiments, the XRD station 350 forwards both the cassette number and the slot number, while in other embodiments, only the slot number is forwarded since the central controller 930 already received the cassette number from the reader 913. Once all of the workpieces have been processed by the XRD station 350, workpieces are transferred to the load lock 920 to be implanted, as shown in Box 1030. If, however, the central controller 930 determines that XRD process has been performed on the workpieces in this cassette, the atmospheric robot 912 transfers workpieces directly to the load lock 920, as shown in Box 1030.

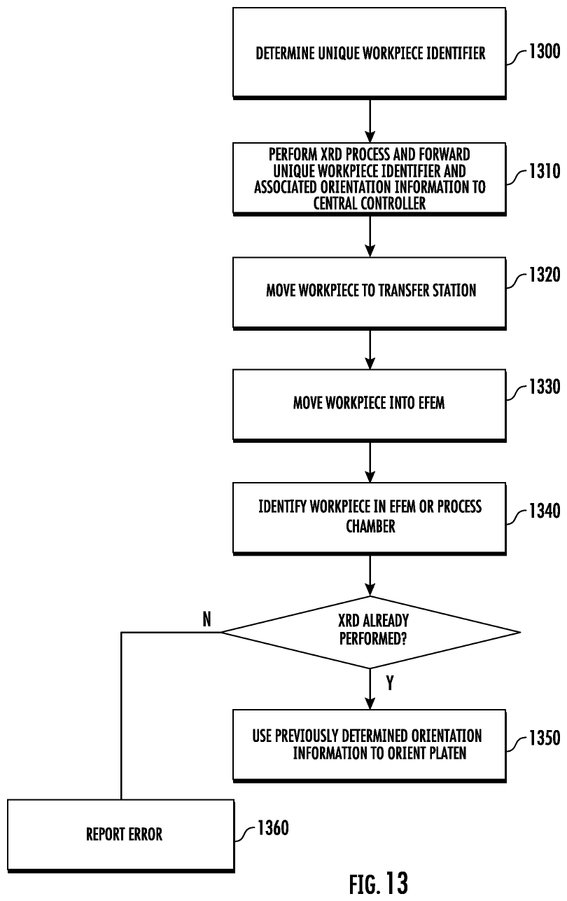

The use of a central controller 930 to correlate a particular workpiece with its optimal orientation may be applied to other configurations. FIG. 12 shows an embodiment where one or more XRD stations 350 are disposed outside the EFEM 910. In this embodiment, the XRD stations 350 are disposed in an atmospheric environment.

An XRD reader 960 may be associated with each XRD station 350. These XRD readers 960, like the XRD stations 350, may be in communication with the central controller 930. In some embodiments, the XRD reader 960 is part of the XRD station 350. In these embodiments, the XRD station 350 may also comprise a transfer station, similar to those in the EFEM 910. Specifically, in this embodiment, the XRD station 350 is able to accept a cassette of workpieces, to read the RFID tag on the cassette, and identify the slot associated with each workpiece to generate the unique workpiece identifier. In another embodiment, the XRD reader 960 may be an OCR reader to detect the serial number on the workpiece. The XRD station 350 then performs the XRD process and relays the unique workpiece identifier and the associated orientation information to the central controller 930, which may save the information in a table or other data structure as described above.

In another embodiment, the XRD station 350 may accept one workpiece at a time. In these embodiments, the XRD reader 960 is external from the XRD station 350. In one embodiment, the XRD reader 960 may accept a cassette, read the RFID tag, extract a workpiece from a slot in the cassette, generate the unique workpiece identifier, and pass the workpiece to the XRD station 350. In another embodiment, the XRD reader 960 may detect the serial number on the workpiece, and pass the workpiece to the XRD station 350.

In some embodiments where the XRD station 350 is disposed outside the EFEM 910, the reader 913 may be located in the EFEM 910. This may be the case where the reader 913 comprises an RFID reader or an OCR reader. In certain embodiments, if the reader 913 is an RFID reader, it may be located within the transfer station 911. In other embodiments, the reader 913 may be disposed in the process chamber 100. This may be the case where the reader 913 is an OCR reader, which may be located at the aligner (not shown). The sequence that may be used for this embodiment is shown in FIG. 13. First, the unique workpiece identifier is detected by one of the XRD readers 960, as shown in Box 1300. In some embodiments, the unique workpiece identifier may be created based on the cassette number and the slot number. In other embodiments, the unique workpiece identifier may be disposed directly on each individual workpiece. The XRD station 350 then performs the rocking curve test and the unique workpiece identifier and the associated orientation information are transmitted to the central controller 930, as shown in Box 1310. At some later time, the workpiece is then transferred to the transfer station 911, as shown in Box 1320. In one embodiment, all of the workpieces within a cassette are processed by the XRD station 350 and the entire cassette is then moved to the transfer station 911. This may be done by an operator, or through the use of an automated robot. Note that this may occur immediately after the workpiece was processed by the XRD station 350, or at a later time. The workpiece is then transferred into the EFEM 910, as shown in Box 1330. Using the reader 913 in the EFEM 910 or the process chamber 100, the unique workpiece identifier of the workpiece is read and the workpiece is identified, as shown in Box 1340. The central controller 930 then checks to ensure that the XRD process has been performed on this workpiece. If so, the central controller 930 retrieves the orientation information associated with this workpiece from the table or other data structure and either directly controls the platen 160, or forwards that orientation information to the controller 280, which then controls the platen 160, as shown in Box 1350. After this, the ion implanter 900 is enabled so that the implantation may be performed. If the central controller 930 detects that an XRD process has not been performed on this workpiece, it may report an error, as shown in Box 1360.

In this configuration, the XRD stations 350 may be remote from the ion implanter 900. As long as the XRD stations 350 and the XRD readers 960 are in communication with the central controller 930, the platen 160 in the ion implanter 900 can be properly oriented.

Note that, in the embodiments shown in FIGS. 10-13, throughput may be improved as the workpiece is only processed by the XRD station 350 once. After that, the central controller 930 simply uses the previously obtained orientation information anytime that the workpiece is to be processed by the ion implanter 900.

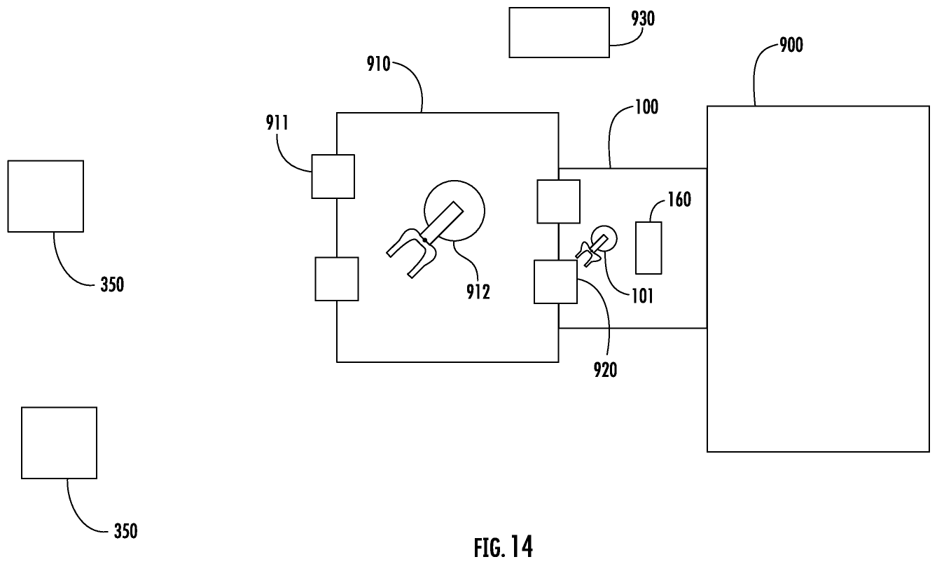

In certain embodiments, there may not be any readers. In this configuration, it is still possible to utilize an XRD station 350 that is disposed outside the EFEM 910. This configuration is shown in FIG. 14. In this embodiment, there may be one or more XRD stations 350. Each XRD station 350 is in communication with the central controller 930.

In one embodiment, each XRD station 350 may include a transfer station, similar to transfer station 911. In this way, an entire cassette, filled with workpieces, may be supplied to the XRD station 350. The XRD station 350 is able to identify each slot, remove a workpiece from that specific slot, and perform the rocking curve test on that workpiece. It then supplies the slot number and the orientation information associated with the workpiece at that slot to the central controller 930, which saves the information in a table or other data structure. It repeats this process for all of the workpieces in the cassette.

This procedure relies on cassettes being introduced into the EFEM 910 in the order in which they were processed by a respective XRD station 350. Specifically, it is expected that the cassette that was processed earliest by the XRD station 350 enters the EFEM 910 first. This may be easily implemented if there is only one XRD station 350. Specifically, when a new cassette enters the ion implanter, the central controller 930 finds orientation information that has not yet been associated with a cassette. It then assumes that this orientation information was just generated by the XRD station 350 and is therefore associated with the cassette that entered the process chamber 100. It then marks this orientation information as used. The central controller 930 then either directly controls the platen 160, or forwards that orientation information to the controller 280, which then controls the platen 160. After this, the ion implanter 900 is enabled so that the implantation may be performed.

However, assume that there are two XRD stations 350. A first cassette is processed by a first of the XRD stations 350, and then a second cassette is processed by a second of the XRD stations. Each XRD station transmits the orientation information associated with all of the workpieces in that cassette to the central controller 930. In some embodiments, the orientation information may be accompanied by a timestamp or an indication of the XRD station that performed the testing. For example, each XRD station may have a unique IP address that the central controller 930 may be aware of. When a new cassette enters the ion implanter, the central controller 930 finds the oldest orientation information that has not yet been associated with a cassette. It then assumes that this oldest orientation information is associated with the workpiece that entered the process chamber 100. It then marks this orientation information as used. The central controller 930 then either directly controls the platen 160, or forwards that orientation information to the controller 280, which then controls the platen 160. After this, the ion implanter 900 is enabled so that the implantation may be performed.

As noted above, in some embodiments, a central controller 930 is used to communicate with the XRD stations 350 and with a separate controller 280, which controls the ion implanter 900. In another embodiment, the configuration shown in FIG. 14 may be simplified by the use of a single controller to perform both these functions. In this embodiment, the XRD station 350 communicates directly with the controller, which also controls the ion implanter 900. Specifically, when a new cassette enters the ion implanter, the controller uses the orientation information that was most recently received from the XRD station 350. The controller then directly controls the platen 160 using this orientation information. After this, the ion implanter 900 is enabled so that the implantation may be performed.

While the above disclosure mentions SiC workpieces, it is understood that the system is not limited to silicon carbide. In one embodiment, if the geometry of the workpieces is known, the Xray source 110 and the Xray detector 130 may be moved to an appropriate angle to satisfy Bragg's equation. The movement of that components may be done manually, or may be controlled by the controller 280.

In another embodiment, the system may be used for workpieces of various geometries. In this embodiment, the collimator 115 shown in FIG. 4 may not be used to allow the emitted Xray beam 120 to have a much broader range of angles. In this embodiment, the Xray source 110 may generate a broad spectrum of energies or wavelengths so that the Bragg equation can be satisfied for a wide range of crystal lattice spacings and scattering angles. This can be achieved by using a tungsten target and high enough electron energy to generate Bremsstrahlung rather than characteristic Xray energies.

In this way, the Bragg equation may be satisfied over a larger range of angles, and one configuration of the Xray source 110 and the Xray detector 130 may be used to accommodate many different crystal types.

In another embodiment, the Xray source 110 may utilize a broad range of angles to determine the type of crystalline structure that the workpiece possesses. Once the crystalline structure is determined, the Xray source 110 and the Xray detector 130 may be moved to the angles that are appropriate for that crystalline structure. For example, the Xray source 110 and the Xray detector 130 may be capable of movement so that they may be moved so as to set an appropriate angle. At this time, the Xray source 110 may also introduce a collimator 115 that allows a narrower range of angles to be utilized for the emitted Xray beam 120. In this way, the controller 280 performs a coarse rocking curve test to determine the crystalline structure then performs a fine rocking curve test to identify the channeling directions.

The embodiments described above in the present application may have many advantages. The use of XRD in the process chamber allows precise control of the incident angle of the ion beam 230. This maximizes the degree of channeling in the workpiece. Channeling may allow deeper implants at a given energy. In some tests, the peak concentration of ions may be 0.5 μm deeper when a channeled implant is performed, as compared to a non-channeled implant. In another test, the concentration of ions may be more box shaped when a channeled implant is performed. Additionally, channeling may reduce the amount of damage done by the implant. In certain embodiments, the amount of damage is sufficiently reduced so that the workpiece is not heated prior to the implant, reducing the time spent in the process chamber. Further, the use of XRD reduces the probability of misoriented workpieces and therefore may result in greater yield.

Furthermore, the embodiments in FIGS. 10-13 improve throughput by only performing the XRD testing on each workpiece once, regardless of how many times it enters the ion implanter. By associating the orientation information collected by the XRD station 350 with a specific workpiece, the central controller may eliminate the need to repeatedly perform the XRD testing. Rather, it simply indexes into a table that comprises a list of unique workpiece identifiers and the orientation information associated with each unique workpiece identifier. This may greatly improve throughput, especially in sequences where there are multiple implantation processes.

Furthermore, the use of a central controller to correlate the unique workpiece identifier and the associated orientation information allows the XRD station to be placed anywhere, even in a separate location. Thus, the XRD station does not have to be incorporated into the process chamber or the EFEM, where there is very limited space.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A system, comprising:
an ion implanter including an ion source to generate an ion beam;
a process chamber comprising a platen to support a workpiece having a crystalline structure;
an equipment front end module (EFEM) in communication with the process chamber via a load lock;
an XRD station to perform a rocking curve test and determine an orientation information for the workpiece based on a result of the rocking curve test to facilitate channeling of the ion beam into the crystalline structure of the workpiece;
a reader associated with the XRD station to detect an identifier, wherein the identifier is used to create a unique workpiece identifier; and
a central controller in communication with the reader and the XRD station, so as to associate the orientation information from the XRD station with the unique workpiece identifier.

2. The system of claim 1, wherein the XRD station is located within the EFEM.

3. The system of claim 2, wherein the workpiece is disposed in a cassette, wherein the cassette includes a cassette number which is the identifier, and a combination of the cassette number and a slot number is used to create the unique workpiece identifier, wherein the reader determines the cassette number based on an RFID tag on the cassette and wherein after receiving the cassette number from the reader, the central controller determines whether an XRD test has already been performed on the workpiece in the cassette.

4. The system of claim 3, further comprising an atmospheric robot disposed in the EFEM, wherein the central controller instructs the atmospheric robot to transfer the workpiece directly to the load lock if the XRD test has already been performed on the workpiece in the cassette and instructs the atmospheric robot to transfer the cassette to the XRD station if the XRD test has not been performed on the workpiece.

5. The system of claim 2, wherein the reader determines the unique workpiece identifier, and after receiving the unique workpiece identifier from the reader, the central controller determines whether an XRD test has already been performed on the workpiece.

6. The system of claim 5, further comprising an atmospheric robot disposed in the EFEM, wherein the central controller instructs the atmospheric robot to transfer the workpiece directly to the load lock if the XRD test has already been performed on the workpiece and instructs the atmospheric robot to transfer the workpiece to the XRD station if the XRD test has not been performed on the workpiece.

7. The system of claim 1, wherein the central controller directly or indirectly controls the platen based on the orientation information associated with the unique workpiece identifier.

8. The system of claim 1, wherein the XRD station is located outside the ion implanter, the EFEM and the process chamber.

9. The system of claim 8, further comprising an additional reader disposed in the EFEM or in the process chamber.

10. The system of claim 9, wherein, after the rocking curve test is performed, the workpiece is transferred from the XRD station to the EFEM, the unique workpiece identifier is detected by the additional reader in the EFEM or in the process chamber, and transmitted to the central controller.

11. The system of claim 10, wherein if the central controller determines that a XRD process was already performed on the workpiece, the central controller directly or indirectly controls the platen based on the orientation information associated with the unique workpiece identifier.

12. The system of claim 10, wherein if the central controller determines that a XRD process was not already performed on the workpiece, the central controller reports an error.

13. The system of claim 9, wherein the workpiece is disposed in a cassette and the reader detects a cassette number and the cassette number is combined with a slot number to create the unique workpiece identifier, and wherein, after the rocking curve test is performed on all workpiece in the cassette, the cassette is transferred from the XRD station to the EFEM, the unique workpiece identifier is detected by the additional reader in the EFEM or in the process chamber, and transmitted to the central controller.

14. The system of claim 8, further comprising:
a second XRD station located outside the EFEM and the process chamber;
a second reader associated with the second XRD station to determine a unique workpiece identifier; and
wherein the central controller in communication with the second reader and the second XRD station, so as to receive the unique workpiece identifier and associate orientation information with that unique workpiece identifier.

15. A system, comprising:
an ion implanter including an ion source to generate an ion beam;
a process chamber comprising a platen to support a workpiece having a crystalline structure;
an equipment front end module (EFEM) in communication with the process chamber via a load lock;
an XRD station to perform a rocking curve test and determine an orientation information for the workpiece based on a result of the rocking curve test to facilitate channeling of the ion beam into the crystalline structure of the workpiece, wherein the XRD station is not located in the EFEM or the process chamber; and
a controller in communication with the XRD station, so as to receive the orientation information from the XRD station and directly or indirectly control the platen based on the orientation information.

16. The system of claim 15, further comprising a second controller dedicated to the ion implanter, wherein the controller forwards the orientation information to the second controller to control the platen.

17. The system of claim 16, further comprising:
a second XRD station located outside the EFEM and the process chamber;
wherein the controller in communication with the second XRD station, so as to receive the orientation information from the second XRD station.

18. A system, comprising:
an ion implanter including an ion source to generate an ion beam;
a process chamber comprising a platen to support a workpiece having a crystalline structure;
a reader; and
a controller in communication with the reader, wherein the controller comprises a table or other data structure that correlates a unique workpiece identifier with orientation information, and wherein the controller receives the unique workpiece identifier from the reader, associates the orientation information with the unique workpiece identifier and directly or indirectly controls the platen based on the orientation information.

19. The system of claim 18, further comprising a second controller dedicated to the ion implanter, wherein the controller forwards the orientation information to the second controller to control the platen.

20. The system of claim 18, further comprising an equipment front end module (EFEM) in communication with the process chamber via a load lock; wherein the reader is disposed in the EFEM or the process chamber.
